(19) United States
(12) Patent Application Publication
(10) Pub. No.: US 2026/0066872 A1
(43) Pub. Date: Mar. 5, 2026

(54) RESONATOR ELEMENT, RESONATOR DEVICE, AND OSCILLATOR

(71) Applicant: SEIKO EPSON CORPORATION, Tokyo (JP)

(72) Inventor: Norihito Matsukawa, Shimosuwa-machi (JP)

(21) Appl. No.: 19/319,335

(22) Filed: Sep. 4, 2025

(30) Foreign Application Priority Data
Sep. 4, 2024 (JP) 2024-152090

(51) Int. Cl. H03H 9/19; H03B 5/32

(52) U.S. Cl. CPC H03H 9/19; H03B 5/32

(57) ABSTRACT

A resonator element includes a substrate made of an SC cut quartz crystal plate, a first excitation electrode disposed on a first surface, and a first coupling electrode electrically coupled to the excitation electrode and provided at one end portion in an X′-axis direction of the substrate, in which the first excitation electrode includes chamfered portions at positions of four corners in a rectangle, and when a width in a Z′-axis direction of a chamfered portion located on a +Z′ side of a first short side is defined as e1, a width in the Z′-axis direction of a chamfered portion located at a −Z′ side of the first short side is defined as e2, a width in the Z′-axis direction of a chamfered portion located on the −Z′ side of a second short side is defined as e3, and a width in the Z′-axis direction of a chamfered portion located on the +Z′ side of the second short side is defined as e4, e1, e2, e3, and e4 satisfy the following expressions (1) to (4):

$$e 2 < e 1 \qquad ( 1 )$$

$$e 4 < e 3 \qquad ( 2 )$$

$$e 2 < e 3 \qquad ( 3 )$$

$$e 4 < e 1. \qquad ( 4 )$$

The present application is based on, and claims priority from JP Application Serial Number 2024-152090, filed Sep. 4, 2024, the disclosure of which is hereby incorporated by reference herein in its entirety.

### BACKGROUND

### 1. Technical Field

The present disclosure relates to a resonator element, a resonator device, and an oscillator.

### 2. Related Art

For example, JP-A-2009-135830 discloses a quartz crystal resonator element capable of suppressing unnecessary vibrations and improving sensitivity, or capable of comprehensively suppressing a plurality of types of unnecessary vibrations. The quartz crystal resonator element is formed of a quartz crystal substrate, and electrodes such as an excitation electrode are formed on the quartz crystal substrate. An edge side constituting at least one of the excitation electrode and a peripheral portion of the quartz crystal substrate is formed in an arc shape in at least a portion thereof.

However, the resonator element described in JP-A-2009-135830 uses an AT cut quartz crystal substrate, and a method of suppressing unnecessary vibrations in an SC cut quartz crystal substrate is not considered.

### SUMMARY

According to an application example of the present disclosure, there is provided a resonator element including a substrate made of an SC cut quartz crystal plate having a first surface orthogonal to a Y″-axis of an orthogonal coordinate system (X′, Y″, Z′) and a second surface opposite to the first surface, a first excitation electrode disposed on the first surface, and a first coupling electrode electrically coupled to the first excitation electrode and provided at one end portion of the substrate in an X′-axis direction, in which the first excitation electrode is a rectangle in a plan view, including a first short side intersecting an X′-axis, a second short side intersecting the X′-axis and located on a +X′ side with respect to the first short side, and a pair of long sides intersecting a Z′-axis, the first excitation electrode includes chamfered portions at positions of four corners of the rectangle, and when a width in a Z′-axis direction of a chamfered portion located on a +Z′ side of the first short side is defined as e1, a width in the Z′-axis direction of a chamfered portion located on a −Z′ side of the first short side is defined as e2, a width in the Z′-axis direction of a chamfered portion located on the −Z′ side of the second short side is defined as e3, and a width in the Z′-axis direction of a chamfered portion located on the +Z′ side of the second short side is defined as e4, then e1, e2, e3, and e4 satisfy the following expressions (1) to (4):

$$e 2 < e 1 \qquad ( 1 )$$

$$e 4 < e 3 \qquad ( 2 )$$

$$e 2 < e 3 \qquad ( 3 )$$

$$e 4 < e 1. \qquad ( 4 )$$

According to an application example of the present disclosure, there is provided a resonator element including a substrate made of an SC cut quartz crystal plate having a first surface orthogonal to a Y″-axis of an orthogonal coordinate system (X′, Y″, Z′) and a second surface opposite to the first surface, a first excitation electrode disposed on the first surface, and a first coupling electrode electrically coupled to the first excitation electrode and provided at one end portion of the substrate in a Z′-axis direction, in which the first excitation electrode is a rectangle, in a plan view, including a fourth short side intersecting a Z′-axis, a fifth short side intersecting a Z′-axis and located on a −Z′ side with respect to the fourth short side, and a pair of long sides intersecting an X′-axis, the first excitation electrode includes chamfered portions at positions of four corners of the rectangle, and when a width in an X′-axis direction of a chamfered portion located on a −X′ side of the fourth short side is defined as e5, a width in the X′-axis direction of a chamfered portion located on the −X′ side of the fifth short side is defined as e6, a width in the X′-axis direction of a chamfered portion located on a +X′ side of the fifth short side is defined as e7, and a width in the X′-axis direction of a chamfered portion located on the +X′ side of the fourth short side is defined as e8, then e5, e6, e7, and e8 satisfy the following expressions (13) to (16):

$$e 6 < e 5 \qquad ( 13 )$$

$$e 8 < e 7 \qquad ( 14 )$$

$$e 6 < e 7 \qquad ( 15 )$$

$$e 8 < e 5. \qquad ( 16 )$$

According to an application example of the present disclosure, there is provided a resonator element including a substrate made of an SC cut quartz crystal plate having a first surface orthogonal to a Y″-axis of an orthogonal coordinate system (X′, Y″, Z′) and a second surface opposite to the first surface, and a first excitation electrode disposed on the first surface and integrally formed, in which the substrate is a rectangle having a pair of sides parallel to an X′-axis and a pair of sides parallel to a Z′-axis, in a plan view, a virtual straight line parallel to the X′-axis and bisecting the first excitation electrode in a Z′ direction is defined as a first virtual line, and a virtual straight line parallel to the Z′-axis and bisecting the first excitation electrode in an X′ direction is defined as a second virtual line, a region of the first excitation electrode on a +Z′ side with respect to the first virtual line and on a −X′ side with respect to the second virtual line is defined as a first region, a region of the first excitation electrode on a −Z′ side with respect to the first virtual line and on the −X′ side with respect to the second virtual line is defined as a second region, a region of the first excitation electrode on the −Z′ side with respect to the first virtual line and on a +X′ side with respect to the second virtual line is defined as a third region, a region of the first excitation electrode on the +Z′ side with respect to the first virtual line and on the +X′ side with respect to the second virtual line is defined as a fourth region, and an area of each of the first region and the third region is smaller than an area of the second region and smaller than an area of the fourth region.

According to an application example of the present disclosure, there is provided a resonator device including the resonator element, and a base configured to support the resonator element by being bonded to the first coupling electrode.

According to an application example of the present disclosure, there is provided an oscillator including the resonator element, an oscillation circuit electrically coupled to the first excitation electrode, and a base in which the resonator element and the oscillation circuit are accommodated.

### BRIEF DESCRIPTION OF THE DRAWINGS

FIG. 1 is a schematic view showing a configuration of a resonator device according to a first embodiment.

FIG. 2 is a schematic sectional view taken along a line II-II in FIG. 1.

FIG. 3A is a view for explaining a cut angle of a substrate.

FIG. 3B is a view for explaining the cut angle of the substrate.

FIG. 4 is a plan view showing a configuration of a resonator element according to a first embodiment.

FIG. 5 is a plan view showing the configuration of the resonator element according to the first embodiment.

FIG. 6 is a plan view showing a configuration of a resonator element according to Modification Example 1 of the first embodiment.

FIG. 7 is a plan view showing a configuration of a resonator device according to Modification Example 2 of the first embodiment.

FIG. 8 is a plan view showing a configuration of a resonator element according to a second embodiment.

FIG. 9 is a plan view showing a configuration of a resonator element according to Modification Example of the second embodiment.

FIG. 10 is a schematic plan view showing a configuration of an oscillator according to a third embodiment.

FIG. 11 is a schematic sectional view taken along a line XI-XI in FIG. 10.

### DESCRIPTION OF EMBODIMENTS

Hereinafter, embodiments according to the present disclosure will be described with reference to the drawings. In each of the following drawings, the scale of each layer and each member is different from the actual scale in order to make each layer and each member have a recognizable size.

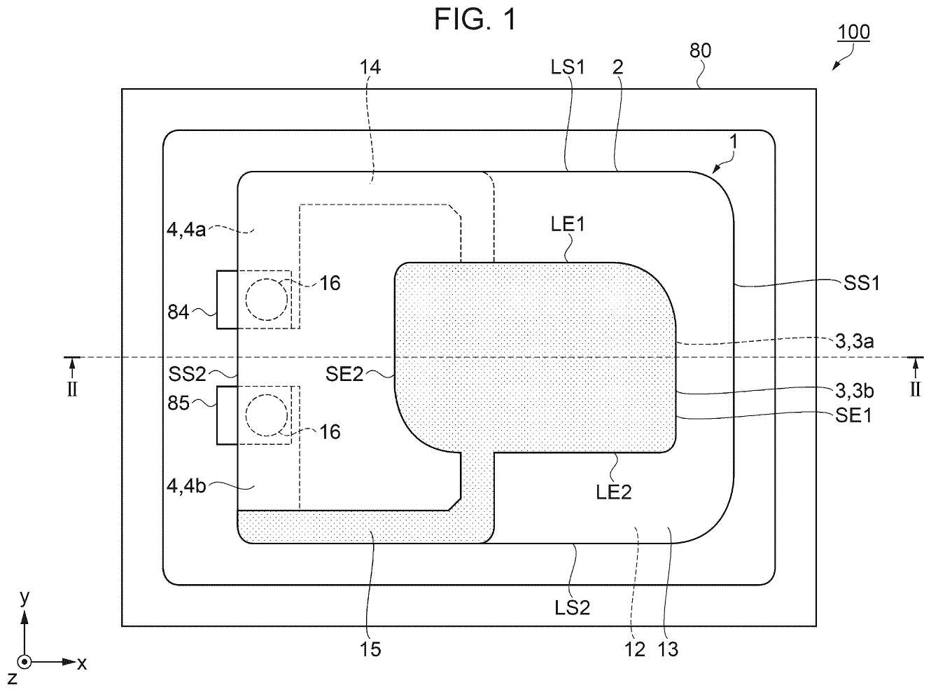

In addition, for convenience of description, an x-axis, a y-axis, and a z-axis are shown as three axes orthogonal to each other in FIGS. 1, 2, 7, 10, 11. In addition, a direction along the x-axis is referred to as an “x-axis direction”, a direction along the y-axis is referred to as a “y-axis direction”, and a direction along the z-axis is referred to as a “z-axis direction”. In addition, an arrow tip end side in each axial direction is also referred to as a “+ side”, and a base end side is also referred to as a “− side”. A plane parallel to the x-axis and the y-axis is also referred to as an “xy plane”. In addition, a plan view when viewed from a +z direction is simply referred to as a “plan view”.

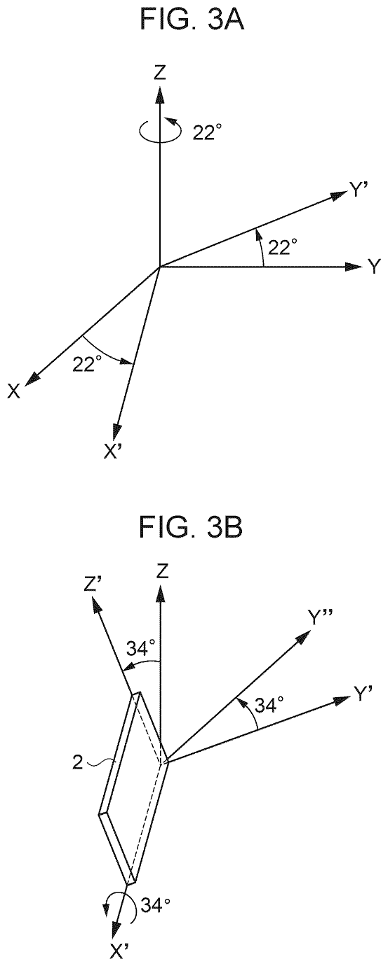

In addition, for convenience of description, in FIGS. 3B, 4 to 6, 8, and 9, X′-axis-, Y″-axis, and Z′-axis are shown as three axes orthogonal to each other, and a tip end side of the shown arrow is set as “+ side” and the base end side is set as “− side”. Further, in the following description, a direction parallel to the X′-axis is referred to as an “X′-axis direction”, a direction parallel to the Y″-axis is referred to as a “Y”-axis direction “, and a direction parallel to the Z”-axis is referred to as a “Z′-axis direction”. Further, for convenience of description, in a plan view when viewed from the Y″-axis direction, a surface in the Y″-axis direction will be described as a main surface. The X′-axis corresponds to the x-axis, and the +X′ direction is the −x direction. The Z′-axis corresponds to the y-axis, and the +Z′ direction is the +y direction. The Y″-axis corresponds to the z-axis, and the +Y″ direction is the +z direction. Therefore, a plan view when viewed from the +Y″ direction is also simply referred to as a “plan view”.

### First Embodiment

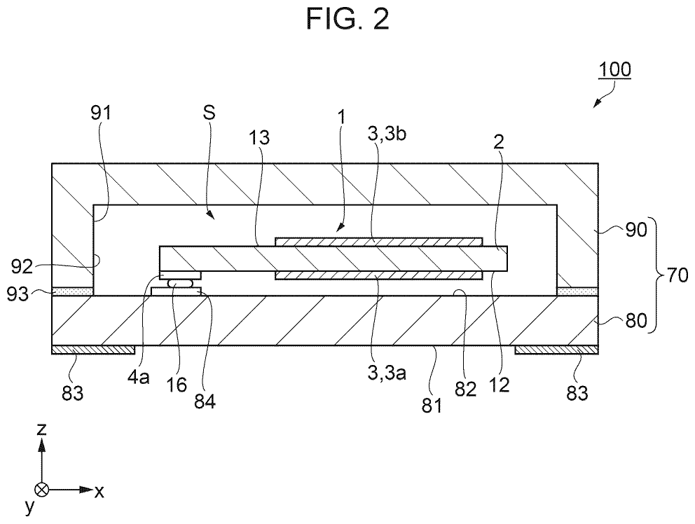

A resonator device 100 according to a first embodiment of the present disclosure will be described with reference to FIGS. 1 and 2. FIG. 1 is a schematic view showing a configuration of the resonator device 100 according to the first embodiment. FIG. 2 is a schematic sectional view taken along a line II-II in FIG. 1. FIG. 1 shows a state in which a lid 90 is removed.

The resonator device 100 is a surface mounting component in which the resonator element 1 is packaged. The resonator device 100 includes a base 80, the resonator element 1, and the lid 90. The base 80 is a flat plate-shaped member that supports the resonator element 1, and the lid 90 is a box-shaped member in which a recessed portion 91 is formed. A package 70 is formed by bonding the base 80 and the lid 90. The resonator element 1 is accommodated in an internal space S of the package 70.

The base 80 has surfaces 81 and 82 that are opposite to each other in the z-axis direction and are parallel to the xy plane. The base 80 has a substantially rectangular shape in a plan view. The base 80 has two external terminals 83 on a surface 81 on the −z side. The base 80 has, on a surface 82 on the +z side, a first electrode pad 84 electrically coupled to one external terminal 83 and a second electrode pad 85 electrically coupled to the other external terminal 83. The first electrode pad 84 and the second electrode pad 85 are disposed side by side along the y-axis direction. The constituent material of the base 80 is silicon, but is not particularly limited, and may be, for example, glass or ceramic.

The lid 90 has a substantially rectangular shape in a plan view and has a box shape having the recessed portion 91 opening in the −z direction. In the lid 90, an opening portion 92 of the recessed portion 91 is bonded to the base 80 via a bonding member 93, and the recessed portion 91 partitions the internal space S accommodating the resonator element 1 together with the base 80. The lid 90 and the base 80 may be directly bonded to each other without using the bonding member 93. In addition, the internal space S is in a reduced pressure state and is preferably in a state closer to vacuum. Thus, viscous resistance is reduced, and oscillation characteristics of the resonator element 1 are improved. The constituent material of the lid 90 is silicon, but is not particularly limited, and may be, for example, glass or ceramic.

The resonator element 1 includes a substrate 2, a pair of excitation electrodes 3, and a pair of coupling electrodes 4.

The substrate 2 has a plate shape parallel to an xy plane formed of quartz crystal and is an SC cut quartz crystal plate to be described later. In FIG. 1, the substrate 2 has a rectangular shape having a pair of long sides LS1 and LS2 and a pair of short sides SS1 and SS2. The long sides LS1 and LS2 extend along the x-axis direction, and the short sides SS1 and SS2 extend along the y-axis direction. The substrate 2 has a first surface 12 and a second surface 13 that are opposite to each other in the z-axis direction. The first surface 12 is a surface on the −z side and faces the base 80. The second surface 13 is a surface on the +z side and faces the lid 90.

The pair of excitation electrodes 3 includes a first excitation electrode 3a disposed on the first surface 12 and a second excitation electrode 3b disposed on the second surface 13. In a plan view, the excitation electrodes 3 have a rectangular shape including a pair of long sides LE1 and LE2 and a pair of short sides SE1 and SE2. The long sides LE1 and LE2 extend along the x-axis direction, the short sides SE1 and SE2 extend along the y-axis direction. The first excitation electrode 3a and the second excitation electrode 3b overlap each other in a plan view.

The pair of coupling electrodes 4 includes a first coupling electrode 4a electrically coupled to the first excitation electrode 3a and a second coupling electrode 4b electrically coupled to the second excitation electrode 3b. The first coupling electrode 4a and the second coupling electrode 4b are disposed on the first surface 12 of the substrate 2 and are arranged in the y-axis direction along the short side SS2 on the −x side. That is, the first coupling electrode 4a and the second coupling electrode 4b are disposed between the short side SS2 and the excitation electrode 3 in a plan view. The substrate 2 includes a lead wire 14, 15, the first coupling electrode 4a is electrically coupled to the first excitation electrode 3a by the lead wire 14, and the second coupling electrode 4b is electrically coupled to the second excitation electrode 3b by the lead wire 15.

The first coupling electrode 4a and the second coupling electrode 4b are bonded to the first electrode pad 84 and the second electrode pad 85 via the bonding member 16 having conductivity. Thus, the resonator element 1 is supported by the base 80. That is, in the substrate 2, a portion where the first coupling electrode 4a and the second coupling electrode 4b are disposed is a support portion. The pair of excitation electrodes 3 generates vibration in the resonator element 1 by applying a voltage supplied from the external terminal 83 to the substrate 2. The material of the bonding member 16 is not particularly limited, and may be an Ag paste or an Au bump.

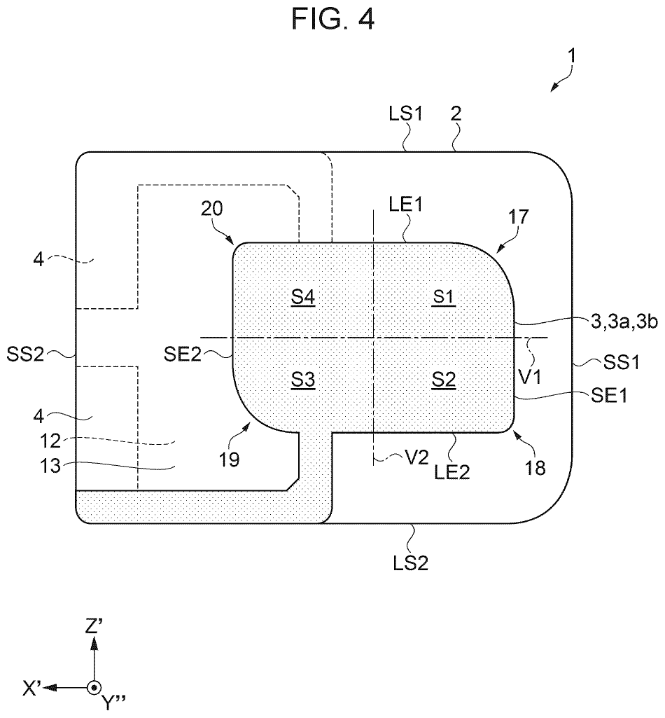

Here, crystal axes of the substrate 2 will be described with reference to FIGS. 3A, 3B, and 4. FIGS. 3A and 3B are views for explaining the cut angle of the substrate 2. FIG. 4 is a plan view showing a configuration of the resonator element 1 according to the first embodiment. As shown in FIG. 3A, the quartz crystal used as the material of the substrate 2 has crystal axes X, Y, and Z orthogonal to each other. An X-axis is referred to as an electrical axis, a Y-axis is referred to as a mechanical axis, and a Z-axis is referred to as an optical axis, respectively. The X-axis, the Y-axis, and the Z-axis are different from the x-axis, the y-axis, and the z-axis in FIGS. 1, 2, 7, 10, 11. An X′-axis and a Y′-axis are formed by rotating the X-axis and the Y-axis counterclockwise about the Z-axis by a predetermined angle of about 22°. As shown in FIG. 3B, a Y″-axis and a Z′-axis are formed by rotating the Y′-axis and the Z-axis counterclockwise about the X′-axis by a predetermined angle of about 34°. The substrate 2 is cut out along an X′Z′ plane parallel to the X′-axis and the Z′-axis. The cut substrate 2 has a surface orthogonal to the Y″-axis. In this way, the SC cut quartz crystal plate is obtained. The SC cut quartz crystal plate is a so-called twice rotated Y cut quartz crystal plate.

The substrate 2 has crystal axes X′, Y″, and Z′ orthogonal to each other, and a thickness direction is the Y″-axis direction. In the substrate 2, a surface that is orthogonal to the Y″-axis and includes the X′-axis and the Z′-axis is a main surface. The substrate 2 has excellent stress sensitivity characteristics, thermal shock resistance characteristics, and the like, with thickness-shear vibration being excited as the main vibration on the main surface.

In FIG. 4, the long sides LS1 and LS2 of the substrate 2 extend along the X′-axis direction, and the short sides SS1 and SS2 extend along the Z′-axis direction. That is, the substrate 2 includes the pair of short sides SS1 and SS2 intersecting the X′-axis and the pair of long sides LS1 and LS2 intersecting the Z′-axis. The first surface 12 of the substrate 2 is a surface on a −Y″ side, and the second surface 13 is a surface on +Y″ side.

In FIG. 4, the long sides LE1 and LE2 of the excitation electrode 3 extend along the X′-axis direction, and the short sides SE1 and SE2 extend along the Z′-axis direction. That is, the short side SE1 intersects the X′-axis, and the short side SE2 intersects the X′-axis and is located on the +X′ side with respect to the short side SE1. The short side SE1 corresponds to a first short side, and the short side SE2 corresponds to a second short side. In addition, the pair of long sides LE1 and LE2 intersects the Z′-axis.

The coupling electrode 4 is provided at one end portion of the substrate 2 in the X′-axis direction and is provided at an end portion on the +X′ side in the present embodiment.

A method of manufacturing the excitation electrode 3 and the coupling electrode 4 will be described. First, a film of chromium (Cr) or the like is formed on the main surface of the substrate 2, and then a film of gold (Au) or the like is laminated on the chromium (Cr). An electrode film of chromium (Cr) or gold (Au) is formed into a desired shape by a method of using a metal mask by a vacuum deposition method, a sputtering method, or the like, or a method of forming a film on the entire main surface of the substrate 2 and then performing metal etching by a photolithography method, or the like. The material for forming the electrode film for enhancing the adhesion between the substrate 2 and the electrode film of gold (Au) is not limited to chromium (Cr) and may be a nickel-chromium (NiCr) alloy or nickel (Ni). Further, the material for forming the electrode film required for obtaining stable vibration characteristics and long-term stability is not limited to gold (Au) and may be platinum (Pt) or silver (Ag).

The shape of the excitation electrode 3 will be described again with reference to FIG. 4. The first excitation electrode 3a and the second excitation electrode 3b are each integrally formed and are not divided. In a plan view, the excitation electrode 3 includes chamfered portions at four corners of the rectangle. The shape of the chamfered portion is an R shape, that is, an arc shape. In a plan view, among the four corner portions, a corner portion located on the −X′ side and the +Z′ side is a first electrode corner portion 17. The remaining corner portions are a second electrode corner portion 18, a third electrode corner portion 19, and a fourth electrode corner portion 20 clockwise from the first electrode corner portion 17 in a plan view. The first electrode corner portion 17 and the third electrode corner portion 19 each have a larger R, that is, a larger chamfer, than the second electrode corner portion 18. In addition, the first electrode corner portion 17 and the third electrode corner portion 19 each have a larger R, that is, a larger chamfer, than the fourth electrode corner portion 20.

A virtual straight line parallel to the X′-axis and bisecting the width of the excitation electrode 3 in the Z′-axis direction is referred to as a first virtual line V1, and a virtual straight line parallel to the Z′-axis and bisecting the width of the excitation electrode 3 in the X′-axis direction is referred to as a second virtual line V2. It is assumed that the excitation electrode 3 is divided into four regions by two virtual lines V1 and V2. Of the four regions, a region located on the −X′ side and the +Z′ side is a first region S1. The remaining regions are a second region S2, a third region S3, and a fourth region S4 clockwise from the first region S1 in a plan view. Due to a difference in the size of R, that is, a difference in the size of the chamfer, an area of the first region S1 and an area of the third region S3 are each smaller than an area of the second region S2 and smaller than an area of the fourth region S4.

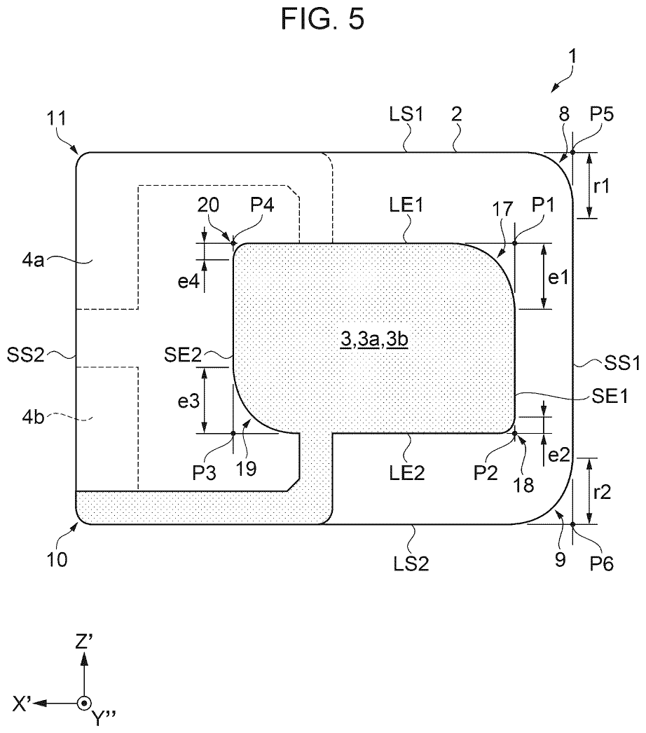

This will be described more specifically with reference to FIG. 5. FIG. 5 is a plan view showing the configuration of the resonator element 1 according to the first embodiment. Four intersections formed when the long sides LE1 and LE2 and the short sides SE1 and SE2 are each virtually extended and intersect each other are defined as intersections P1 to P4. An intersection of the first electrode corner portion 17 is P1, an intersection of the second electrode corner portion 18 is P2, an intersection of the third electrode corner portion 19 is P3, and an intersection of the fourth electrode corner portion 20 is P4.

A distance from the intersections P1 to P4 to a straight portion of the short side SE1 and a straight portion of the short side SE2, that is, a width of the chamfer of each of the corner portions is e1 at the first electrode corner portion 17, e2 at the second electrode corner portion 18, e3 at the third electrode corner portion 19, and e4 at the fourth electrode corner portion 20. That is, the width e1 is a width of the chamfered portion located on the +Z′ side of the first short side in the Z′-axis direction. The width e2 is a width of the chamfered portion located on the −Z′ side of the first short side in the z′-axis direction. The width e3 is a width of the chamfered portion located on the −Z′ side of the second short side in the Z′-axis direction. The width e4 is a width of the chamfered portion located on the +Z′ side of the second short side in the Z′-axis direction.

At this time, the widths e1 to e4 satisfy all of the following expressions (1) to (4).

$$e 2 < e 1 \qquad ( 1 )$$

$$e 4 < e 3 \qquad ( 2 )$$

$$e 2 < e 3 \qquad ( 3 )$$

$$e 4 < e 1 \qquad ( 4 )$$

In this way, the shape of the excitation electrode 3 can be made suitable for a position of the main vibration. In addition, the excitation electrode 3 is not disposed in a region that does not contribute to excitation, thereby suppressing coupling of unnecessary high-order mode vibration due to the plate thickness with the main vibration in the excitation electrode 3. Therefore, in the substrate 2 formed of the SC cut quartz crystal plate, it is possible to improve the vibration characteristics of the resonator element 1 by suppressing the coupling of the unnecessary sub-vibration with the main vibration while maintaining the size of the area of the excitation electrode 3.

It is desirable that the width e1 and the width e3 are smaller than ½ times the width of the excitation electrode 3 in the Z′-axis direction. Thus, it is possible to suppress an increase in equivalent series resistance in the resonator element 1 and to stabilize the oscillation of the main vibration.

Next, a corner portion of the substrate 2 will be described with reference to FIG. 5. The substrate 2 includes chamfered portions at four corner portions of the rectangle. The shape of the chamfered portion is an R shape, that is, an arc shape. Of the four corner portions, a corner portion on the −X′ side and the +Z′ side is a first substrate corner portion 8. The remaining corner portions are a second substrate corner portion 9, a third substrate corner portion 10, and a fourth substrate corner portion 11 clockwise from the first substrate corner portion 8 in a plan view. In a plan view, the first substrate corner portion 8 and the second substrate corner portion 9 are provided on the side opposite to the first coupling electrode 4a and the second coupling electrode 4b with respect to the excitation electrode 3. In a plan view, the third substrate corner portion 10 and the fourth substrate corner portion 11 are provided on the same side as the first coupling electrode 4a and the second coupling electrode 4b with respect to the excitation electrode 3. The first substrate corner portion 8 and the second substrate corner portion 9 have a larger R, that is, a larger chamfer, than the third substrate corner portion 10 and the fourth substrate corner portion 11.

The chamfer of the substrate 2 in the present embodiment is to form the R shape of the four corner portions simultaneously with the four sides of the rectangle when the substrate 2 is extracted from the quartz crystal plate as a material by etching. However, the method of forming the four sides and the four corner portions of the rectangle is not limited to this and may be processing using polishing or grinding.

The substrate 2 has chamfered portions at both ends of the short side SS1 on the −X′ side. The short side SS1 corresponds to a third short side. Two intersections formed when the long sides LS1 and LS2 and the short side SS1 are virtually extended and intersect each other are defined as intersections P5 and P6. The intersection of the first substrate corner portion 8 is P5, and the intersection of the second substrate corner portion 9 is P6.

A distance from the intersection P5 to the straight portion of the short side SS1, that is, a chamfered width of the first substrate corner portion 8 is r1. A distance from the intersection P6 to the straight portion of the short side SS1, that is, a chamfered width of the second substrate corner portion 9 is r2. That is, the width r1 is a width of the chamfered portion located on the +Z′ side of the third short side in the Z′-axis direction. The width r2 is a width of the chamfered portion located on the −Z′ side of the third short side in the Z′-axis direction.

At this time, the widths r1 and r2 in the substrate 2 and the widths e2 and e4 in the excitation electrode 3 satisfy all of the following expressions (5) to (8).

$$e 2 < r 1 \qquad ( 5 )$$

$$e 4 < r 2 \qquad ( 6 )$$

$$e 2 < r 2 \qquad ( 7 )$$

$$e 4 < r 1 \qquad ( 8 )$$

In this way, since it is possible to suppress unnecessary vibrations caused by the corner portion of the substrate 2, it is possible to further improve the vibration characteristics of the resonator element 1.

The third short side has been described as the short side SS1 on the −X′ side, but is not particularly limited thereto. The third short side may be a short side located on the side opposite to the first coupling electrode 4a and the second coupling electrode 4b with respect to the excitation electrode 3. That is, when the first coupling electrode 4a and the second coupling electrode 4b are disposed on the −X′ side with respect to the excitation electrode 3, the third short side may be the short side SS2 on the −+X′ side.

The first coupling electrode 4a and the second coupling electrode 4b have been described as being disposed between the short sides SS2 and the excitation electrode 3 in a plan view in FIG. 1, but the present disclosure is not particularly limited thereto, and for example, the first coupling electrode 4a and the second coupling electrode 4b may be disposed between the short sides SS1 and the excitation electrode 3.

In the above description, the base 80 is a flat plate-shaped member, and the lid 90 has a box shape having the recessed portion 91. However, the present disclosure is not particularly limited thereto. For example, the base 80 may have a box shape having a recessed portion, and the lid 90 may be a flat plate-shaped member. As a combination, the base 80 may have a box shape made of a ceramic material as a constituent material, and the lid 90 may have a flat plate shape made of metal as a constituent material.

The shape of the excitation electrode 3 is not limited to a rectangle and may be any shape such as a square, an ellipse, a circle, or a rhombus.

The R shape of the chamfered portion of the excitation electrode 3 and the chamfered portion of the substrate 2 is not limited to an arc shape having a constant radius R. For example, the size of the radius R may vary in the chamfered portion as long as the chamfered portion includes a convex curve in a plan view.

Although the shape of the chamfered portion of the excitation electrode 3 and the chamfered portion of the substrate 2 has been described as an R shape, the shape is not particularly limited thereto and may be, for example, a shape having a straight portion intersecting the X′-axis and the Z′-axis, that is, a C surface shape, or a shape having a curved portion and a straight portion.

In the chamfered portion of the excitation electrode 3, the shape may be different for each corner portion. For example, the first electrode corner portion 17 and the third electrode corner portion 19 may have an R shape, and the second electrode corner portion 18 and the fourth electrode corner portion 20 may have a C surface shape.

The shape of the substrate 2 is not limited to a rectangle, and may be, for example, a square.

In the chamfered portion of the substrate 2, the shape may be different for each corner portion. For example, the first substrate corner portion 8 and the third substrate corner portion 10 may have an R shape, and the second substrate corner portion 9 and the fourth substrate corner portion 11 may have a C surface shape.

In a plan view, the shape of the first excitation electrode 3a and the shape of the second excitation electrode 3b are not limited to being completely identical. For example, one of the corner portion of the first excitation electrode 3a and the corner portion of the second excitation electrode 3b, which overlap each other in a plan view, may have an R shape, and the other may have a C surface shape. Alternatively, both may have an R shape, and the sizes of R may be different from each other.

As described above, in the present embodiment, the chamfered portion of the excitation electrode 3 and the chamfered portion of the substrate 2 have a shape having a straight portion intersecting the X′-axis and the Z′-axis or an arc shape in a plan view. In this way, the chamfered shape can be selected according to the size of the resonator element 1, the position of the chamfered portion, the manufacturing method, or the like. That is, it is possible to provide the resonator element 1 with increased design freedom and reduced manufacturing costs.

In FIG. 1, it has been described that the first coupling electrode 4a and the second coupling electrode 4b are arranged in the y-axis direction along the short side SS2 on the −x side, but the present disclosure is not particularly limited thereto, and the first coupling electrode 4a and the second coupling electrode 4b may be arranged in the y-axis direction along the short side SS1 on the +x side. In any case, the resonator element 1 is fixed to the base 80 by two point support. Accordingly, it is possible to stabilize the fixed state for a long period of time while suppressing the influence of the support stress. Therefore, it is possible to provide the resonator element 1 with high reliability.

Although the substrate 2 has been described as having a flat plate shape, the shape in the plate thickness direction is not particularly limited thereto. For example, a position where the excitation electrode 3 is provided may have a forward mesa shape or an inverted mesa shape. Alternatively, a convex shape or a bevel shape may be used. In addition, in these cases, one surface may be a flat surface and the other surface may be a concave or convex surface.

As described above, the resonator device 100 according to the present embodiment includes the resonator element 1 and the base 80 which is bonded to the first coupling electrode 4a to support the resonator element 1. In this way, it is possible to suppress the coupling of the unnecessary sub-vibration to the main vibration in the resonator element 1 and to provide the resonator device 100 having excellent vibration characteristics.

### Modification Example 1 of First Embodiment

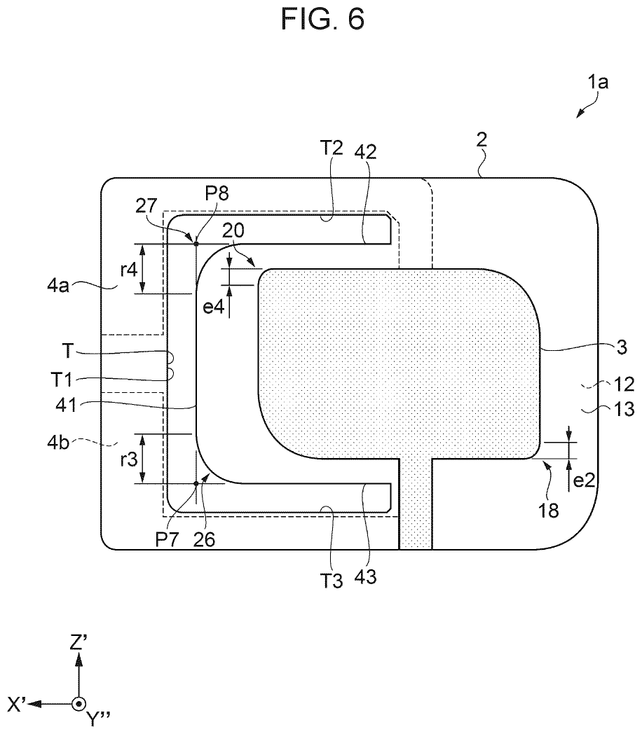

A Modification Example 1 of the first embodiment will be described with reference to FIG. 6. FIG. 6 is a plan view showing a configuration of a resonator element 1a according to Modification Example 1 of the first embodiment. Further, in FIG. 6, the same reference numerals are assigned to the same configurations as those of the above-described embodiment. Differences from the first embodiment will be mainly described, and the description of the same matters will be omitted.

The substrate 2 includes a slit T between the excitation electrode 3 and the first coupling electrode 4a and the second coupling electrode 4b. The slit T penetrates from the first surface 12 to the second surface 13 in the Y″-axis direction of a resonator element 1a. The slit T includes, in a plan view, a first portion T1 extending along the Z′-axis direction, a second portion T2 coupled to an end portion of the first portion T1 on the +Z′ side and extending in the −X′ direction, and a third portion T3 coupled to an end portion of the first portion T1 on the −Z′ side and extending in the −X′ direction. The first portion T1 is located between the excitation electrode 3 and the first coupling electrode 4a and the second coupling electrode 4b. The second portion T2 is located on the +Z′ side of the excitation electrode 3. The third portion T3 is located on the −Z′ side of the excitation electrode 3.

A side of the substrate 2 on the excitation electrode 3 side that partitions a portion of the first portion T1 is a side 41. A side of the substrate 2 on the excitation electrode 3 side that partitions a portion of the second portion T2 is a side 42. A side of the substrate 2 on the excitation electrode 3 side that partitions a portion of the third portion T3 is a side 43.

On the −X′ side of the first portion T1 and the +Z′ side of the third portion T3, a corner portion of the substrate 2 that partitions a portion of the slit T is a fifth substrate corner portion 26. On the −X′ side of the first portion T1 and the −Z′ side of the second portion T2, a corner portion of the substrate 2 that partitions a portion of the slit T is a sixth substrate corner portion 27.

That is, the fifth substrate corner portion 26 is a corner at which virtual straight lines extending respectively from the side 41 and the side 43 intersect each other, and the sixth substrate corner portion 27 is a corner at which virtual straight lines respectively extending from the side 41 and the side 42 intersect each other. The fifth substrate corner portion 26 and the sixth substrate corner portion 27 are chamfered and have an R shape. The chamfered portion of the fifth substrate corner portion 26 corresponds to a first chamfered portion, and the chamfered portion of the sixth substrate corner portion 27 corresponds to a second chamfered portion. The chamfers of the fifth substrate corner portion 26 and the sixth substrate corner portion 27 are larger than the chamfers of the second electrode corner portion 18 and the fourth electrode corner portion 20.

This will be described more specifically. Two intersections formed when the side 41, the side 42, and the side 43 are each virtually extended and intersect each other are defined as P7 and P8 in order from the −Z′ side. The intersection of the fifth substrate corner portion 26 is P7, and the intersection of the sixth substrate corner portion 27 is P8.

A distance from the intersection P7 to the straight portion of the side 41, that is, a width of the chamfer at the fifth substrate corner portion 26, is r3. A distance from the intersection P8 to the straight portion of the side 41, that is, a width of the chamfer at the sixth substrate corner portion 27, is r4. In other words, the width r3 is a width in the Z′-axis direction of the first chamfered portion located at the corner where the virtual straight lines extending respectively from the side 41 and the side 43 intersect. The width r4 is a width in the Z′-axis direction of the second chamfered portion located at the corner where the virtual straight lines extending respectively from the side 41 and the side 42 intersect.

At this time, the widths r3 and r4 in the substrate 2 and the widths e2 and e4 in the excitation electrode 3 satisfy all of the following expressions (9) to (12).

$$e 2 < r 4 \qquad ( 9 )$$

$$e 4 < r 3 \qquad ( 10 )$$

$$e 2 < r 3 \qquad ( 11 )$$

$$e 4 < r 4 \qquad ( 12 )$$

In this way, it is possible to suppress the unnecessary vibrations, and it is possible to suppress the frequency fluctuation and the deterioration of aging characteristics caused by the influence of support stress generated by the bonding between the resonator element 1a and the base 80.

The slit T is not necessarily limited to including the first portion T1, the second portion T2, and the third portion T3. For example, the slit T may not include the second portion T2 and may not include the third portion T3. Alternatively, the slit T may not include the second portion T2 and the third portion T3. At least a portion of the slit T may be provided between the first coupling electrode 4a and the excitation electrode 3.

In addition, a direction in which the first portion T1 extends is not necessarily limited to being along the Z′-axis, and for example, may be inclined from the Z′-axis.

In addition, the slit T is not particularly limited to being constituted by one through-hole. For example, a non-through portion may be provided between the first portion T1 and the second portion T2, or the first portion T1 may be configured by a plurality of through portions arranged along the Z′-axis.

### Modification Example 2 of First Embodiment

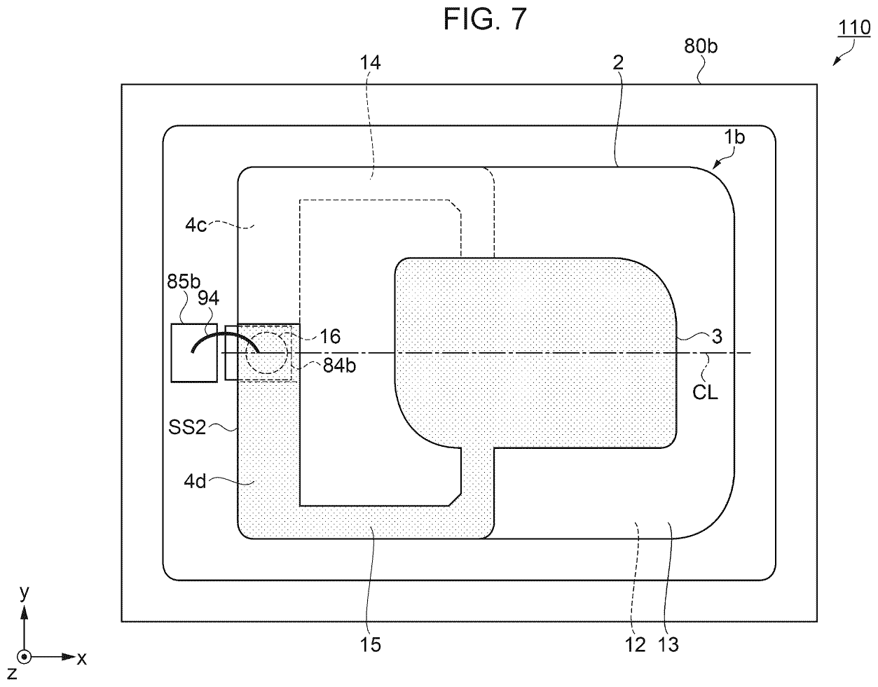

Modification Example 2 of the first embodiment will be described with reference to FIG. 7. FIG. 7 is a plan view showing a configuration of a resonator device 110 according to Modification Example 2 of the first embodiment. FIG. 7 shows a state in which the lid 90 (see FIG. 2) is removed. Further, in FIG. 7, the same reference numerals are assigned to the same configurations as those of the above-described embodiment. Differences from the first embodiment will be mainly described, and the description of the same matters will be omitted.

The resonator device 110 according to Modification Example 2 includes a base 80b, a resonator element 1b, and the lid 90. The resonator device 110 according to Modification Example 2 is the same as the resonator device 100 according to the first embodiment except that the structure of the resonator element 1b and the structure of the base 80b are different.

In the resonator element 1b, the first coupling electrode 4c and the second coupling electrode 4d are disposed between the short side SS2 on the −x side and the excitation electrodes 3 in a plan view. The first coupling electrode 4c is disposed on the first surface 12 of the substrate 2, and the second coupling electrode 4d is disposed on the second surface 13 of the substrate 2. A portion of the first coupling electrode 4c and a portion of the second coupling electrode 4d overlap each other at a position where a center line CL in the y-axis direction of the resonator element 1b passes through, in a plan view.

In the base 80b, the first electrode pad 84b and the second electrode pad 85b are disposed side by side along the x-axis direction. The second electrode pad 85b is disposed on the −x side with respect to the first electrode pad 84b. The first electrode pad 84b is disposed at a position overlapping a portion of the first coupling electrode 4c in a plan view. The second electrode pad 85b is disposed on the −x side with respect to the second coupling electrode 4d in a plan view, and at least a portion thereof is exposed from the resonator element 1b.

The first coupling electrode 4c is bonded to the first electrode pad 84b via the bonding member 16 having conductivity. The second coupling electrode 4d is electrically coupled to the second electrode pad 85b via bonding wires 94.

With such a configuration, the resonator element 1b can be fixed to the base 80b by one point support. Thus, the influence of the support stress can be further reduced.

### Second Embodiment

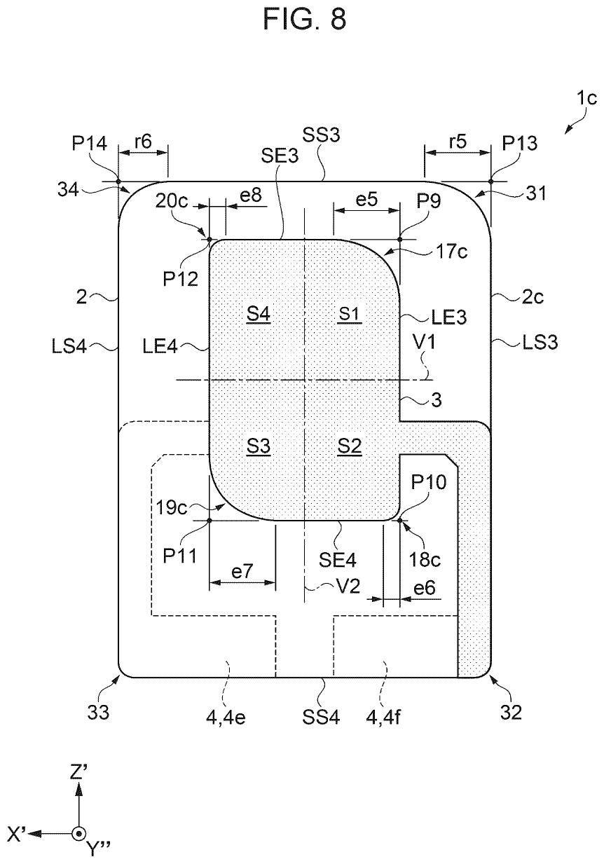

A resonator element 1c according to a second embodiment will be described with reference to FIG. 8. FIG. 8 is a plan view showing a configuration of the resonator element 1c according to the second embodiment.

The resonator element 1c of the second embodiment includes a substrate 2c, a pair of excitation electrodes 3, and a pair of coupling electrodes 4. The resonator element 1c of the second embodiment is the same as the resonator element 1 of the first embodiment except that the orientations of the crystal axes X′ and Z′ in the resonator element 1c are different.

In FIG. 8, in a plan view, the long sides LS3 and LS4 of the substrate 2c extend along the Z′-axis direction, and the short sides SS3 and SS4 extend along the X′-axis direction. In a plan view, the long sides LE3 and LE4 of the excitation electrode 3 extend along the Z′-axis direction, and the short sides SE3 and SE4 extend along the X′-axis direction. That is, the short side SE3 intersects the Z′-axis, and the short side SE4 intersects the Z′-axis and is located on the −Z′ side with respect to the short side SE3. The short side SE3 corresponds to a fourth short side, and the short side SE4 corresponds to a fifth short side. In addition, the pair of long sides LE3 and LE4 intersects the X′-axis.

Of the four corner portions of the excitation electrode 3, a corner portion located on the −X′ side and the +Z′ side in a plan view is a fifth electrode corner portion 17c. The remaining corner portions are a sixth electrode corner portion 18c, a seventh electrode corner portion 19c, and an eighth electrode corner portion 20c clockwise from the fifth electrode corner portion 17c in a plan view. The fifth electrode corner portion 17c and the seventh electrode corner portion 19c have a larger R, that is, a larger chamfer, than the sixth electrode corner portion 18c and the eighth electrode corner portion 20c.

In the excitation electrode 3, four intersections formed when four sides are virtually extended and intersect each other are defined as intersections P9 to P12. An intersection of the fifth electrode corner portion 17c is P9, an intersection of the sixth electrode corner portion 18c is P10, an intersection of the seventh electrode corner portion 19c is P11, and an intersection of the eighth electrode corner portion 20c is P12.

A distance from the intersections P9 to P12 to a straight portion of the short side SE3 and a straight portion of the short side SE4, that is, a width of the chamfer of each of the corner portions is e5 at the fifth electrode corner portion 17c, e6 at the sixth electrode corner portion 18c, e7 at the seventh electrode corner portion 19c, and e8 at the eighth electrode corner portion 20c. That is, the width e5 is a width in the X′-axis direction of the chamfered portion located on the −X′ side of the fourth short side. The width e6 is a width in the X′-axis direction of the chamfered portion located on the −X′ side of the fifth short side. The width e7 is a width in the X′-axis direction of the chamfered portion located on the +X′ side of the fifth short side. The width e8 is a width in the X′-axis direction of the chamfered portion located on the +X′ side of the fourth short side.

At this time, e5 to e8 satisfy all of the following expressions (13) to (16).

$$e 6 < e 5 \qquad ( 13 )$$

$$e 8 < e 7 \qquad ( 14 )$$

$$e 6 < e 7 \qquad ( 15 )$$

$$e 8 < e 5 \qquad ( 16 )$$

In this way, it is possible to dispose the excitation electrode 3 according to a position of the main vibration. Therefore, in the SC cut quartz crystal substrate, it is possible to improve the vibration characteristics of the resonator element 1c by suppressing the coupling of the unnecessary sub-vibration with the main vibration while maintaining the size of the area of the excitation electrode 3.

In the substrate 2c, of the four corner portions, a corner portion on the −X′ side and the +Z′ side is a seventh substrate corner portion 31. The remaining corner portions are an eighth substrate corner portion 32, a ninth substrate corner portion 33, and a tenth substrate corner portion 34 clockwise from the seventh substrate corner portion 31. The substrate 2c includes chamfered portions at both ends of the short side SS3 on the +Z′ side, that is, at the seventh substrate corner portion 31 and the tenth substrate corner portion 34. The short side SS3 corresponds to a sixth short side.

Two intersections formed when the long sides LS3 and LS4 and the short side SS3 on the +Z′ side are virtually extended and intersect each other are defined as intersections P13 and P14. An intersection of the seventh substrate corner portion 31 is P13, and an intersection of the tenth substrate corner portion 34 is P14. A distance from the intersection P13 to the straight portion of the short side SS3, that is, a chamfered width of the seventh substrate corner portion 31 is r5. A distance from the intersection P14 to the straight portion of the short side SS3, that is, a chamfered width of the tenth substrate corner portion 34 is r6. That is, the width r5 is a width in the X′-axis direction of the chamfered portion located on the −X′ side of the sixth short side. The width r6 is a width in the X′-axis direction of the chamfered portion located on the +X′ side of the sixth short side.

At this time, the widths r5 and r6 and the widths e6 and e8 of the excitation electrode 3 satisfy all of the following expressions (17) to (20).

$$e 6 < r 5 \qquad ( 17 )$$

$$e 8 < r 5 \qquad ( 18 )$$

$$e 8 < r 6 \qquad ( 19 )$$

$$e 6 < r 6 \qquad ( 20 )$$

In this way, since it is possible to suppress unnecessary vibrations caused by the corner portion of the substrate 2c, it is possible to further improve the vibration characteristics of the resonator element 1c.

The sixth short side has been described as the short side SS3 on the +Z′ side, but is not particularly limited thereto. The sixth short side may be a short side located on the side opposite to a first coupling electrode 4e and a second coupling electrode 4f with respect to the excitation electrode 3. That is, when the first coupling electrode 4e and the second coupling electrode 4f are disposed on the +Z′ side with respect to the excitation electrode 3, the sixth short side may be the short side SS4 on the −Z′ side.

### Modification Example of Second Embodiment

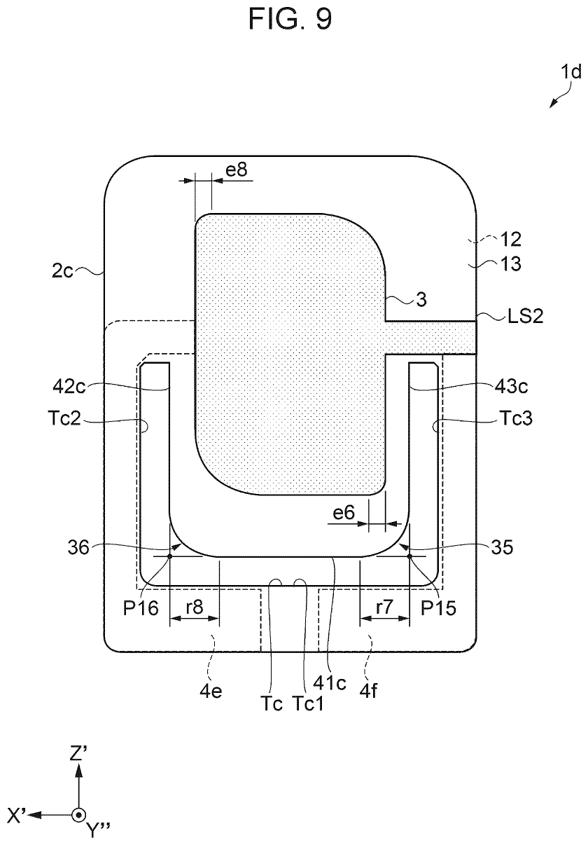

Modification Example of the second embodiment will be described with reference to FIG. 9. FIG. 9 is a plan view showing a configuration of a resonator element 1d according to Modification Example of the second embodiment. Further, in FIG. 9, the same reference numerals are assigned to the same configurations as those of the above-described embodiment. Differences from the second embodiment will be mainly described, and the description of the same matters will be omitted.

The substrate 2c includes a slit Tc between the excitation electrode 3 and the first coupling electrode 4e and the second coupling electrode 4f. The slit Tc penetrates from the first surface 12 to the second surface 13 in the Y″-axis direction of the resonator element 1d. The slit Tc includes, in a plan view, a first portion Tc1 extending along the X′-axis direction, a second portion Tc2 coupled to an end portion of the first portion Tc1 on the +X′ side and extending in the +Z′ direction, and a third portion Tc3 coupled to an end portion of the first portion Tc1 on the −X′ side and extending in the +Z′ direction. The second portion Tc2 is located on the +X′ side of the excitation electrode 3. The third portion Tc3 is located on the −X′ side of the excitation electrode 3.

On the +Z′ side of the first portion Tc1 and the +X′ side of the third portion Tc3, a corner portion of the substrate 2c that partitions a portion of the slit Tc is an eleventh substrate corner portion 35. On the +Z′ side of the first portion Tc1 and the −X′ side of the second portion Tc2, a corner portion of the substrate 2c that partitions a portion of the slit Tc is a twelfth substrate corner portion 36. The eleventh substrate corner portion 35 and the twelfth substrate corner portion 36 are chamfered and have an R shape. The chamfered portion of the eleventh substrate corner portion 35 corresponds to a third chamfered portion, and the chamfered portion of the twelfth substrate corner portion 36 corresponds to a fourth chamfered portion.

A side of the substrate 2c on the excitation electrode 3 side that partitions a portion of the first portion Tc1 is a side 41c. A side of the substrate 2c on the excitation electrode 3 side that partitions a portion of the second portion Tc2 is a side 42c. A side of the substrate 2c on the excitation electrode 3 side that partitions a portion of the third portion Tc3 is a side 43c.

Two intersections formed when the side 41c, the side 42c, and the side 43c are each virtually extended and intersect each other are defined as P15 and P16 in order from the −X′ side.

A distance from the intersection P15 to the straight portion of the side 41c, that is, a chamfered width of the eleventh substrate corner portion 35 is r7. A distance from the intersection P16 to the straight portion of the side 41c, that is, a chamfered width of the twelfth substrate corner portion 36 is r8. In other words, the width r7 is a width in the X′-axis direction of the third chamfered portion located at the corner where the virtual straight lines extending respectively from the side 41c and the side 43c intersect. The width r8 is a width in the X′-axis direction of the fourth chamfered portion located at the corner where the virtual straight lines extending respectively from the side 41c and the side 42c intersect.

At this time, the widths r7 and r8 in the substrate 2c and the widths e6 and e8 in the excitation electrode 3 satisfy all of the following expressions (21) to (24).

$$e 6 < r 7 \qquad ( 21 )$$

$$e 8 < r 8 \qquad ( 22 )$$

$$e 6 < r 8 \qquad ( 23 )$$

$$e 8 < r 7 \qquad ( 24 )$$

In this way, it is possible to suppress the unnecessary vibrations, and it is possible to suppress the frequency fluctuation and the deterioration in aging characteristics caused by the influence of the support stress generated by the bonding between the resonator element 1d and the base 80.

### Third Embodiment

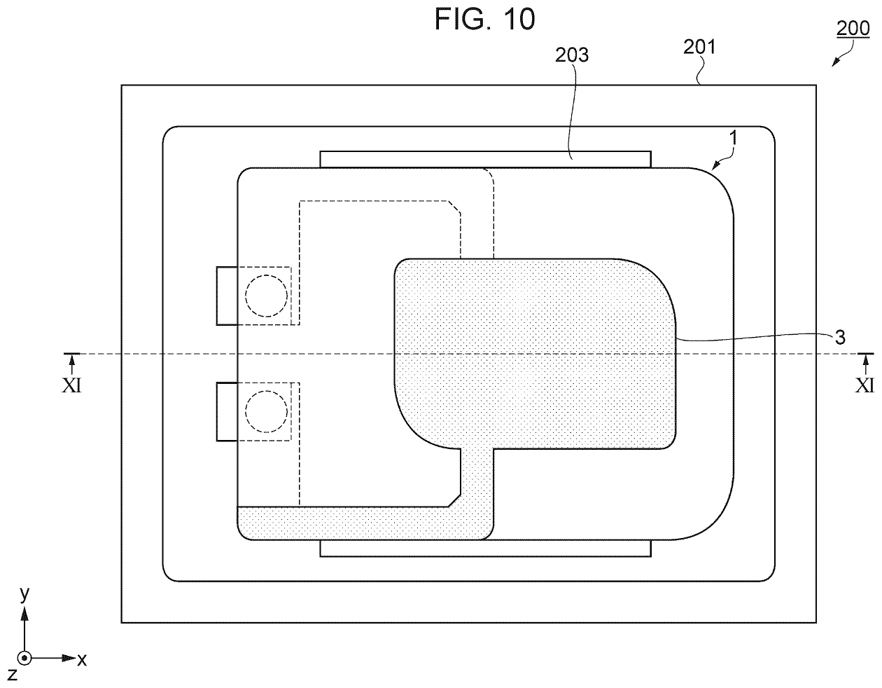

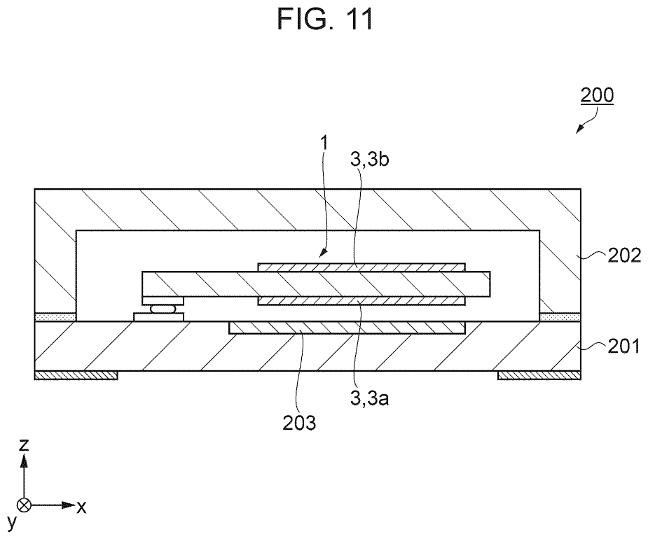

An oscillator 200 according to a third embodiment will be described with reference to FIGS. 10 and 11 by taking a quartz crystal oscillator including the resonator element 1 described above as an example. FIG. 10 is a schematic plan view showing a configuration of the oscillator 200. FIG. 11 is a schematic sectional view taken along a line XI-XI in FIG. 10. In FIG. 10, for convenience of description of an internal configuration of the oscillator 200, a state in which the lid 202 is removed is shown.

The oscillator 200 includes a base 201, a lid 202, the resonator element 1, and an oscillation circuit 203.

The structure of the oscillator 200 is substantially the same as that of the resonator device 100 according to the first embodiment except that the oscillation circuit 203 is provided on the base 201. The oscillation circuit 203 is electrically coupled to the excitation electrode 3 provided in the resonator element 1 and can excite the resonator element 1.

In this way, it is possible to provide the oscillator 200 having excellent vibration characteristics by suppressing the coupling of the unnecessary sub-vibration to the main vibration.

The above has been described based on the embodiments of the resonator elements 1, 1a to 1d, the resonator devices 100 and 110, and the oscillator 200. However, the present embodiment is not limited thereto, and the configuration of each unit can be replaced with any configuration having the same function. In addition, any other component may be added to the present embodiment. In addition, each embodiment may be combined as appropriate.

What is claimed is:

1. A resonator element comprising:
a substrate made of an SC cut quartz crystal plate having a first surface orthogonal to a Y″-axis of an orthogonal coordinate system (X′, Y″, Z′) and a second surface opposite to the first surface;
a first excitation electrode disposed on the first surface; and
a first coupling electrode electrically coupled to the first excitation electrode and provided at one end portion of the substrate in an X′-axis direction, wherein
the first excitation electrode is a rectangle in a plan view, including a first short side intersecting an X′-axis, a second short side intersecting the X′-axis and located on a +X′ side with respect to the first short side, and a pair of long sides intersecting a Z′-axis,
the first excitation electrode includes chamfered portions at positions of four corners of the rectangle, and
when a width in a Z′-axis direction of a chamfered portion located on a +Z′ side of the first short side is defined as e1,
a width in the Z′-axis direction of a chamfered portion located on a −Z′ side of the first short side is defined as e2,
a width in the Z′-axis direction of a chamfered portion located on the −Z′ side of the second short side is defined as e3, and
a width in the Z′-axis direction of a chamfered portion located on the +Z′ side of the second short side is defined as e4,
e1, e2, e3, and e4 satisfy the following expressions (1) to (4):
$$e 2 < e 1 \qquad ( 1 )$$
$$e 4 < e 3 \qquad ( 2 )$$
$$e 2 < e 3 \qquad ( 3 )$$
$$e 4 < e 1. \qquad ( 4 )$$

2. A resonator element comprising:
a substrate made of an SC cut quartz crystal plate having a first surface orthogonal to a Y″-axis of an orthogonal coordinate system (X′, Y″, Z′) and a second surface opposite to the first surface;
a first excitation electrode disposed on the first surface; and
a first coupling electrode electrically coupled to the first excitation electrode and provided at one end portion of the substrate in a Z′-axis direction, wherein
the first excitation electrode is a rectangle in a plan view, including a fourth short side intersecting a Z′-axis, a fifth short side intersecting the Z′-axis and located on a −Z′ side with respect to the fourth short side, and a pair of long sides intersecting an X′-axis,
the first excitation electrode includes chamfered portions at positions of four corners of the rectangle, and
when a width in an X′-axis direction of a chamfered portion located on a −X′ side of the fourth short side is defined as e5,
a width in the X′-axis direction of a chamfered portion located on the −X′ side of the fifth short side is defined as e6,
a width in the X′-axis direction of a chamfered portion located on a +X′ side of the fifth short side is defined as e7, and
a width in the X′-axis direction of a chamfered portion located on the +X′ side of the fourth short side is defined as e8,
e5, e6, e7, and e8 satisfy the following expressions (13) to (16):
$$e 6 < e 5 \qquad ( 13 )$$
$$e 8 < e 7 \qquad ( 14 )$$
$$e 6 < e 7 \qquad ( 15 )$$
$$e 8 < e 5. \qquad ( 16 )$$

3. The resonator element according to claim 1, wherein
the substrate is a rectangle in a plan view, including a pair of short sides intersecting the X′-axis and a pair of long sides intersecting the Z′-axis,
the substrate includes chamfered portions at both ends of a third short side of the pair of short sides, the third short side being located on a side opposite to the one end portion in the X′-axis direction, and
when a width in the Z′-axis direction of a chamfered portion located on the +Z′ side of the third short side is defined as r1, and
a width in the Z′-axis direction of a chamfered portion located on the −Z′ side of the third short side is defined as r2,
e2, e4, r1, and r2 satisfy the following expressions (5) to (8):
$$e 2 < r 1 \qquad ( 5 )$$
$$e 4 < r 2 \qquad ( 6 )$$
$$e 2 < r 2 \qquad ( 7 )$$
$$e 4 < r 1. \qquad ( 8 )$$

4. The resonator element according to claim 2, wherein
the substrate is a rectangle in a plan view, including a pair of short sides intersecting the Z′-axis and a pair of long sides intersecting the X′-axis,
the substrate includes chamfered portions at both ends of a sixth short side of the pair of short sides, the sixth short side being located on a side opposite to the one end portion in the Z′-axis direction, and
when a width in the X′-axis direction of a chamfered portion located on the −X′ side of the sixth short side is defined as r5, and
a width in the X′-axis direction of a chamfered portion located on the +X′ side of the sixth short side is defined as r6,
e6, e8, r5, and r6 satisfy the following expressions (17) to (20):
$$e 6 < r 5 \qquad ( 17 )$$
$$e 8 < r 5 \qquad ( 18 )$$
$$e 8 < r 6 \qquad ( 19 )$$
$$e 6 < r 6. \qquad ( 20 )$$

5. The resonator element according to claim 1, wherein
the substrate has a slit penetrating from the first surface to the second surface, and
at least a portion of the slit is provided between the first coupling electrode and the first excitation electrode.

6. The resonator element according to claim 1, wherein
the substrate includes a slit penetrating from the first surface to the second surface,
the slit includes
a first portion located between the first coupling electrode and the first excitation electrode and extending along the Z′-axis,
a second portion located on the +Z′ side of the first excitation electrode and extending along the X′-axis,
a third portion located on the −Z′ side of the first excitation electrode and extending along the X′-axis,
a first chamfered portion located at a corner where virtual straight lines extending respectively from a side of the first portion on the first excitation electrode side and from a side of the third portion on the first excitation electrode side intersect, and
a second chamfered portion located at a corner where virtual straight lines extending respectively from the side of the first portion on the first excitation electrode side and from a side of the second portion on the first excitation electrode side intersect, and
when a width of the first chamfered portion in the Z′-axis direction is defined as r3, and
a width of the second chamfered portion in the Z′-axis direction is defined as r4,
e2, e4, r3, and r4 satisfy the following expressions (9) to (12):
$$e 2 < r 4 \qquad ( 9 )$$
$$e 4 < r 3 \qquad ( 10 )$$
$$e 2 < r 3 \qquad ( 11 )$$
$$e 4 < r 4. \qquad ( 12 )$$

7. The resonator element according to claim 2, wherein
the substrate includes a slit penetrating from the first surface to the second surface,
the slit includes
a first portion located between the first coupling electrode and the first excitation electrode and extending along the X′-axis,
a second portion located on the +X′ side of the first excitation electrode and extending along the Z′-axis,
a third portion located on the −X′ side of the first excitation electrode and extending along the Z′-axis,
a third chamfered portion located at a corner where virtual straight lines extending respectively from a side of the first portion on the first excitation electrode side and from a side of the third portion on the first excitation electrode side intersect, and
a fourth chamfered portion located at a corner where virtual straight lines extending respectively from the side of the first portion on the first excitation electrode side and from a side of the second portion on the first excitation electrode side intersect, and
when a width of the third chamfered portion in the X′-axis direction is defined as r7, and
a width of the fourth chamfered portion in the X′-axis direction is defined as r8,
e6, e8, r7, and r8 satisfy the following expressions (21) to (24):
$$e 6 < r 7 \qquad ( 21 )$$
$$e 8 < r 8 \qquad ( 22 )$$
$$e 6 < r 8 \qquad ( 23 )$$
$$e 8 < r 7. \qquad ( 24 )$$

8. The resonator element according to claim 1, wherein
the chamfered portion has, in a plan view, a shape including a straight portion intersecting the X′-axis and the Z′-axis or an arc shape.

9. The resonator element according to claim 1, further comprising:
a second excitation electrode disposed on the second surface; and
a second coupling electrode electrically coupled to the second excitation electrode, wherein
the first coupling electrode and the second coupling electrode are disposed side by side along a short side of the substrate on the first surface.

10. The resonator element according to claim 1, further comprising:
a second excitation electrode disposed on the second surface; and
a second coupling electrode electrically coupled to the second excitation electrode, wherein
the first coupling electrode is disposed on the first surface, and the second coupling electrode is disposed on the second surface, and
the first coupling electrode and the second coupling electrode overlap each other in a plan view.

11. A resonator element comprising:
a substrate made of an SC cut quartz crystal plate having a first surface orthogonal to a Y″-axis of an orthogonal coordinate system (X′, Y″, Z′) and a second surface opposite to the first surface; and
a first excitation electrode disposed on the first surface and integrally formed, wherein
the substrate is a rectangle having a pair of sides parallel to an X′-axis and a pair of sides parallel to a Z′-axis,
in a plan view, a virtual straight line parallel to the X′-axis and bisecting the first excitation electrode in a Z′ direction is defined as a first virtual line, and a virtual straight line parallel to the Z′-axis and bisecting the first excitation electrode in an X′ direction is defined as a second virtual line,
a region of the first excitation electrode on a +Z′ side with respect to the first virtual line and on a −X′ side with respect to the second virtual line is defined as a first region,
a region of the first excitation electrode on a −Z′ side with respect to the first virtual line and on the −X′ side with respect to the second virtual line is defined as a second region,
a region of the first excitation electrode on the −Z′ side with respect to the first virtual line and on a +X′ side with respect to the second virtual line is defined as a third region,
a region of the first excitation electrode on the +Z′ side with respect to the first virtual line and on the +X′ side with respect to the second virtual line is defined as a fourth region, and
an area of the first region and an area of the third region are each smaller than an area of the second region and smaller than an area of the fourth region.

12. A resonator device comprising:
the resonator element according to claim 1; and
a base configured to support the resonator element by being bonded to the first coupling electrode.

13. An oscillator comprising:
the resonator element according to claim 1;
an oscillation circuit electrically coupled to the first excitation electrode; and
a base in which the resonator element and the oscillation circuit are accommodated.
